(19) United States
(12) Patent Application Publication
(10) Pub. No.: US 2007/0166869 A1
(43) Pub. Date: Jul. 19, 2007

(54) METHOD FOR DRIVING PIXELS OF AN ORGANIC LIGHT EMITTING DISPLAY

(75) Inventors: JUNG-CHIEH CHENG, CHANGHUA COUNTY (TW); TAI-MING LIN, TAIPEI CITY (TW); I-CHENG SHIH, TAOYUAN COUNTY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taipei (TW)

(21) Appl. No.: 11/689,522

(22) Filed: Mar. 22, 2007

Related U.S. Application Data
(62) Division of application No. 11/161,130, filed on Jul. 25, 2005.

(51) Int. Cl. H01L 21/00

(52) U.S. Cl. 438/82

(57) ABSTRACT

A circuit and a method for driving pixels of an organic light-emitting display are provided. The circuit comprises a thin-film transistor having a source terminal connected to a voltage source, a storage capacitor having a first terminal connected to a gate terminal of the thin-film transistor, and an organic light-emitting diode having a cathode connected to a ground. The gate terminal and a drain terminal of the thin-film transistor are connected in a clamping phase and a reverse phase. A second terminal of the storage capacitor is connected to the ground in the clamping phase, and is connected to a data line in a light-emitting phase and in the reverse phase. An anode of the organic light-emitting diode is connected to the drain terminal of the thin-film transistor in the light-emitting phase and in the reverse phase.

### CROSS-REFERENCE TO RELATED APPLICATION

This application is a divisional of a prior application Ser. No. 11/161,130, filed Jul. 25, 2005, now allowed. The entirety of each of the above-mentioned patent application is hereby incorporated by reference herein and made a part of this specification.

### BACKGROUND OF THE INVENTION

1. Field of the Invention

The present invention relates to a circuit and a method for driving an organic light emitting display. More particularly, the present invention relates to a circuit and a method for driving pixels of an organic light emitting display.

2. Description of the Related Art

Organic light-emitting displays based on organic light-emitting diodes have many advantages, such as spontaneous light emission, high luminance, high contrast, wide viewing angle and fast response. Therefore, scientists and engineers have been making a lot of effort on research and development of characteristics of and driving circuits for organic light-emitting displays. However, although organic light-emitting displays have the advantages mentioned above, there are still some problems waiting to be solved.

FIG. 1 depicts a basic circuit for driving the organic light-emitting diode OLED that is part of a pixel of an organic light-emitting display. When the thin-film transistor (TFT) T2 connected to the scan line SL is turned on, a data voltage is stored into the storage capacitor Cs. And then the data voltage stored in the storage capacitor Cs determines the current passing through the TFT T1, and thereby determines the brightness of the organic light-emitting diode OLED. This driving circuit is simple. However, it has some problems such as threshold voltage shift and shortened material lifetime of organic light-emitting diodes.

Drifting threshold voltage means that the threshold voltages of driving switches tend to vary because of factors such as time and fabrication process. The current through organic light-emitting diodes also tends to vary according to the drifting. Consequently, the brightness of pixels of an organic light-emitting display is often discordant even when the pixels receive identical data signals. For solving this problem, the article by H. Kageyama et. al. and titled “A 2.5-inch OLED Display with a Three-TFT Pixel Circuit for Clamped Inverter Driving” (SID2004) proposed the circuit depicted in FIG. 2. The circuit in FIG. 2 clamps and stores the threshold voltage factor (V_{DD}−Vₜₕ, where Vₜₕ is the threshold voltage of the TFT T1) into the storage capacitor Cs by switching the TFT T2 and T3. Later, during the period with an external electric field of the organic light-emitting diode OLED, the voltage stored in the storage capacitor Cs will cancel out the threshold voltage of the TFT T1. In this way, the problem of discordant brightness caused by threshold voltage shift is solved.

About material lifetime of organic light-emitting diodes. The article by Dechun Zou et. al. and titled “Improvement of Current-Voltage Characteristics in Organic Light Emitting Diodes by Application of Reversed-Bias Voltage” (Japanese Journal of Applied Physics, vol. 37, pp. L1406-L1408, 1998) disclosed the polarization phenomenon induced during the period with an external electric field of organic light-emitting diodes. Please refer to FIG. 3 and FIG. 4. FIG. 3 shows the random distribution of ionic impurities inside an organic light-emitting diode during its period without an external electric field (that is, when the diode does not emit light), while FIG. 4 shows the distribution of the ionic impurities during the period with an external electric field of the diode. In the period with an external electric field, the external electric field E across the organic light-emitting diode separates positive charges and negative charges in the ionic impurities. Therefore the internal reverse electric field R is generated in response to the external electric field E. This is the polarization phenomenon. The polarization phenomenon not only shortens material lifetime of organic light-emitting diodes, but also hinders the movement of electrons and holes inside the diodes and reduces the light-emitting efficiency of the diodes.

Against the polarization phenomenon, the article by Si Yujuan et. al. and titled “A Simple and Effective AC Pixel Driving Circuit for Active Matrix OLED” (IEEE Transactions on Electron Devices, vol. 50, issue 4, pp. 1137-1141, April 2003) proposed the circuit depicted in FIG. 5. The voltage source Vref in FIG. 5 switches between 0V and a high voltage so that the organic light-emitting diode OLED is reverse-biased periodically. The reverse bias serves to join the separated positive and negative charges to eliminate the polarization phenomenon. Therefore the circuit in FIG. 5 is capable of prolonging the material lifetime of organic light-emitting diodes and enhancing the movement of electrons and holes inside the diodes.

As can be seen from the above, so far the prior art can solve only one of the polarization phenomenon and the problem of threshold voltage shift. One of the goals of the present invention is solving the polarization phenomenon and the problem of threshold voltage shift at the same time.

### SUMMARY OF THE INVENTION

Accordingly, the present invention is directed to a circuit for driving pixels of an organic light-emitting display. The circuit is able to solve the problem of discordant brightness caused by threshold voltage shift. The circuit is also capable of solving the problem of polarization to prolong the material lifetime of organic light-emitting diode and to enhance the movement of electrons and holes.

The present invention is also directed to a method for driving pixels of an organic light-emitting display. The method advances the clamping of the threshold voltage of the driving switch so that the timing control of the switches in the pixel driving circuit can be relaxed.

According to an embodiment of the present invention, a circuit for driving pixels of an organic light-emitting display is provided. The circuit comprises a thin-film transistor having a source terminal connected to a voltage source, a storage capacitor having a first terminal connected to a gate terminal of the thin-film transistor, and an organic light-emitting diode having a cathode connected to a ground. When the circuit is in a clamping phase, the gate terminal of the thin-film transistor is connected to a drain terminal of the thin-film transistor and a second terminal of the storage capacitor is connected to the ground. When the circuit is in a light-emitting phase, the second terminal of the storage capacitor is connected to a data line and an anode of the organic light-emitting diode is connected to the drain terminal of the thin-film transistor. Finally, when the circuit is in a reverse phase, the gate terminal of the thin-film transistor is connected to the drain terminal of the thin-film transistor, the second terminal of the storage capacitor is connected to the data line, and the anode of the organic light-emitting diode is connected to the drain terminal of the thin-film transistor.

In an embodiment of the present invention, when the circuit is in the light-emitting phase, the circuit receives a data voltage and a reference voltage from the data line. Moreover, the data voltage and the reference voltage determine a conducting time of the thin-film transistor.

In an embodiment of the present invention, the reference voltage is a triangular voltage signal.

In an embodiment of the present invention, when the circuit is in the reverse phase, the circuit receives a negative voltage from the data line.

According to another embodiment of the present invention, a method for driving pixels of an organic light-emitting display is provided. The method is characterized by storing a threshold voltage of a thin-film transistor in a storage capacitor before a switch connected to a scan line is turned on.

In an embodiment of the present invention, the thin-film transistor drives an organic light-emitting diode.

In an embodiment of the present invention, the method further comprises the step of determining a conducting time of the thin-film transistor according to a data voltage and a reference voltage.

In an embodiment of the present invention, the method further comprises the step of applying a reverse bias across the organic light-emitting diode during a period without an external electric field of the organic light-emitting diode.

The present invention solves the problem of discordant brightness by storing the threshold voltage of the driving switch in a storage capacitor to cancel out the threshold voltage itself. The present invention also uses reverse bias to eliminate the polarization phenomenon to prolong the material lifetime of organic light-emitting diode and to enhance the movement of electrons and holes. Besides, the present invention advances the clamping of the threshold voltage of the driving switch without occupying the light emitting period of the organic light-emitting diode. Therefore the timing control of the switches in the pixel driving circuit can be relaxed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 and FIG. 2 are schematic diagrams showing prior art circuits for driving pixels of an organic light-emitting display.

FIG. 3 and FIG. 4 are schematic diagrams showing the polarization phenomenon in an organic light-emitting diode.

FIG. 5 is a schematic diagram showing a prior art circuit for driving pixels of an organic light-emitting display.

FIG. 6 is a schematic diagram showing a circuit for driving pixels of an organic light-emitting display according to an embodiment of the present invention.

FIG. 7 is a schematic diagram showing the variation of the voltage at the gate terminal of the driving switch in a circuit for driving pixels of an organic light-emitting display according to an embodiment of the present invention.

FIG. 8 is a schematic diagram showing the operation of a circuit for driving pixels of an organic light-emitting display according to an embodiment of the present invention.

FIG. 9 is a schematic diagram showing an equivalent of a circuit for driving pixels of an organic light-emitting display according to an embodiment of the present invention.

FIG. 10 and FIG. 11 are schematic diagrams showing the operation of a circuit for driving pixels of an organic light-emitting display according to an embodiment of the present invention.

FIG. 12 is a schematic diagram showing an equivalent of a circuit for driving pixels of an organic light-emitting display according to an embodiment of the present invention.

FIG. 13 and FIG. 14 are schematic diagrams showing the operation of a circuit for driving pixels of an organic light-emitting display according to an embodiment of the present invention.

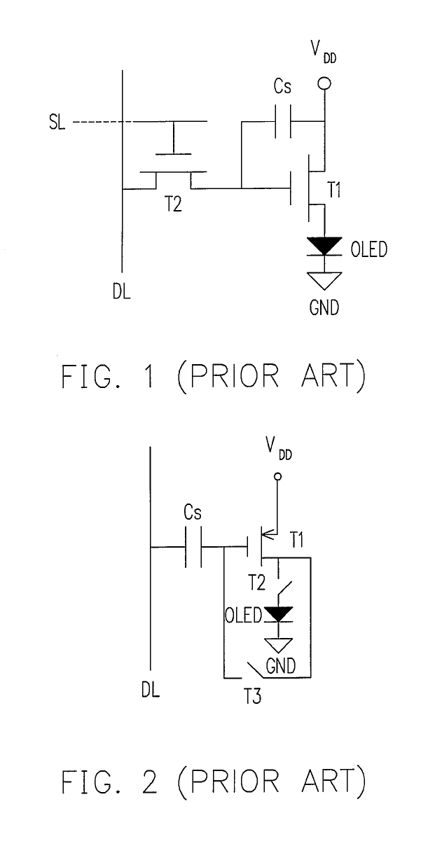

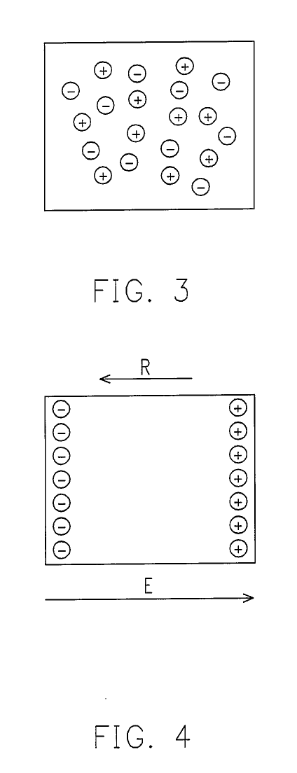

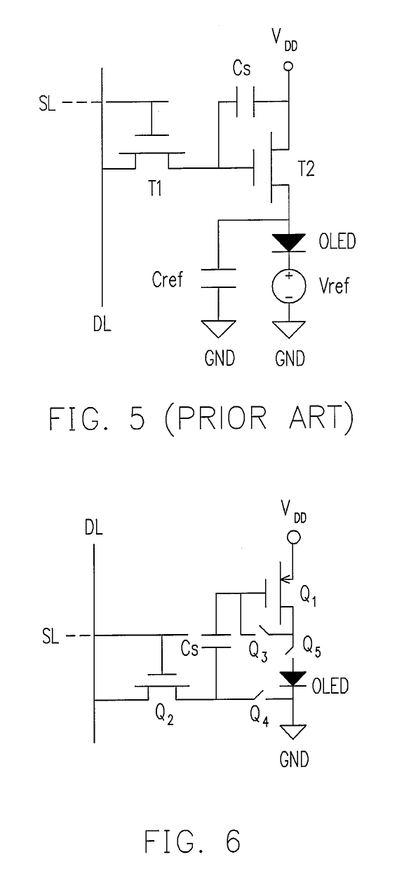

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 6 is a schematic diagram showing a circuit for driving pixels of an organic light-emitting display according to an embodiment of the present invention. The circuit in this embodiment comprises the thin-film transistor Q₁˜Q₅, the storage capacitor Cs, and the organic light-emitting diode OLED. The thin-film transistor Q₁ has a source terminal connected to the voltage source V_{DD} and a gate terminal connected to the first terminal of the storage capacitor Cs. The cathode of the organic light-emitting diode OLED is connected to the ground GND. The TFT Q₂ connects or disconnects the second terminal of the storage capacitor Cs and the data line DL in response to a signal received from the scan line SL. The TFT Q₃ is connected between the gate terminal and the drain terminal of the thin-film transistor Q₁. The TFT Q₄ is connected between the second terminal of the storage capacitor Cs and the ground GND. The TFT Q₅ is connected between the drain terminal of the thin-film transistor Q₁ and the anode of the organic light-emitting diode OLED. In this embodiment, the TFT Q₁ is also known as the driving switch, because Q₁ drives the organic light-emitting diode OLED.

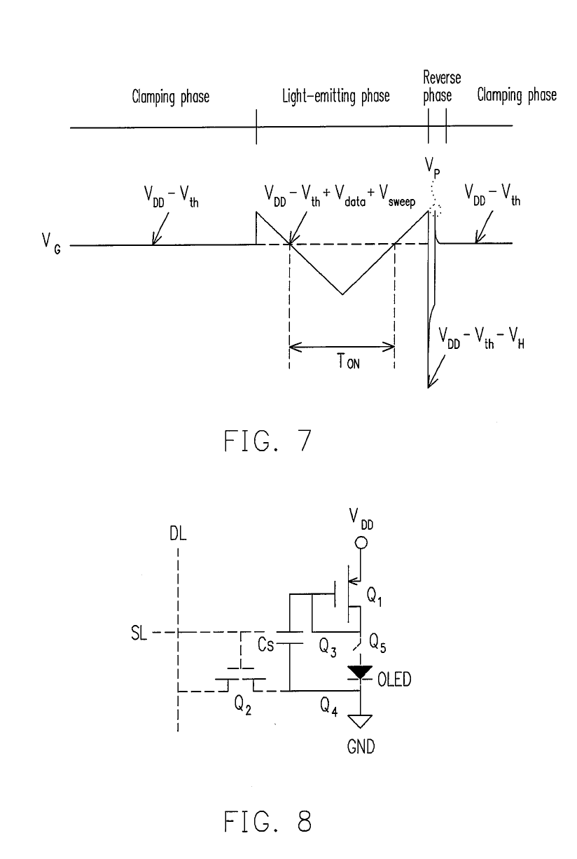

In this embodiment, the operation of the circuit in FIG. 6 is divided into three phases. They are the clamping phase, the light-emitting phase, and the reverse phase. The light-emitting phase follows the clamping phase. The reverse phase follows the light-emitting phase. And the clamping phase follows the reverse phase. The three phases form a continuous cycle. FIG. 7 shows the variation of the voltage V_{G} at the gate terminal of the driving switch Q₁ of the circuit in FIG. 6 in the three operating phases. The details are discussed below.

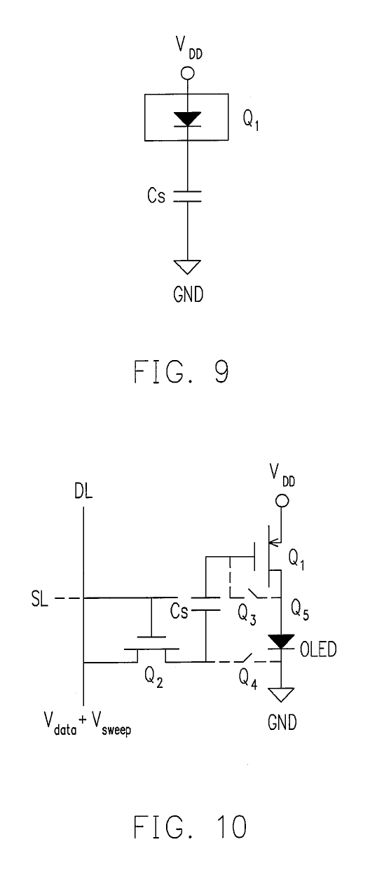

In the clamping phase, the thin-film transistors Q₁, Q₃ and Q₄ are turned on, whereas Q₂ and Q₅ are turned off. Therefore the gate terminal and the drain terminal of the thin-film transistor Q₁ are connected together. And the second terminal of the storage capacitor Cs is connected to the ground GND. The connection of the above components in the clamping phase is shown in solid lines in FIG. 8. The driving switch Q₁ in the clamping phase is equivalent to a diode and the circuit in FIG. 8 is equivalent to the circuit depicted in FIG. 9. The voltage across the diode Q1 is the threshold voltage Vₜₕ of the thin-film transistor Q₁. The voltage across the storage capacitor Cs is equal to (V_{DD}−Vₜₕ), and is equal to the voltage V_{G} at the gate terminal of the thin-film transistor Q₁, as depicted in FIG. 7. At this moment, the threshold voltage factor V_{DD}−Vₜₕ has been clamped and stored in the storage capacitor Cs.

In the light-emitting phase, the thin-film transistors Q₁, Q₂ and Q₅ are turned on, whereas Q₃ and Q₄ are turned off. Therefore the second terminal of the storage capacitor Cs is connected to the data line DL and the anode of the organic light-emitting diode OLED is connected to the drain terminal of the thin-film transistor Q₁. The connection of the above components is shown in solid lines in FIG. 10. In the light-emitting phase, the data voltage V_{data} and the reference voltage V_{sweep} are provided to the data line DL, raising the voltage V_{G} at the gate terminal of Q₁ to (V_{DD}−Vₜₕ+V_{data}+V_{sweep}), as depicted in FIG. 7. To turn on the driving switch Q1, the inequality V_{DD}−V_{G}>Vₜₕ must be satisfied. In other words, the inequality V_{DD}−(V_{DD}−Vₜₕ+V_{data}+V_{sweep})>Vₜₕ must be satisfied. It can be easily deduced that to turn on the driving switch Q₁ and to have the organic light-emitting diode OLED emit light, the voltages mentioned above have to satisfy the inequality (V_{data}+V_{sweep})<0. Please note that the threshold voltage Vₜₕ does not appear in the last inequality. Thanks to the voltage clamping, the threshold voltage Vₜₕ of the driving switch Q₁ appears on both sides of the inequality and cancels out itself. Therefore the problem caused by the threshold voltage shift Vₜₕ is solved.

As shown in the above discussions, the length of the conducting time of the thin-film transistor Q₁ and the light emitting period of the organic light-emitting diode OLED is determined by the data voltage V_{data} and the reference voltage V_{sweep}. As shown in FIG. 7, in this embodiment, the data voltage V_{data} is a DC (direct current) voltage, while the reference voltage V_{sweep} is a fixed triangular voltage signal. When the inequality (V_{data}+V_{sweep})<0 is satisfied, the voltage V_{G} is smaller than V_{DD}−Vₜₕ. Therefore the period Ton in FIG. 7 is when the organic light-emitting diode OLED emits light. In this embodiment, the waveform of the reference voltage V_{sweep} is fixed, and the data voltage V_{data} varies with pixel data in order to control the length of the period Ton, in which the organic light-emitting diode OLED emits light, and thereby control the brightness of the diode OLED.

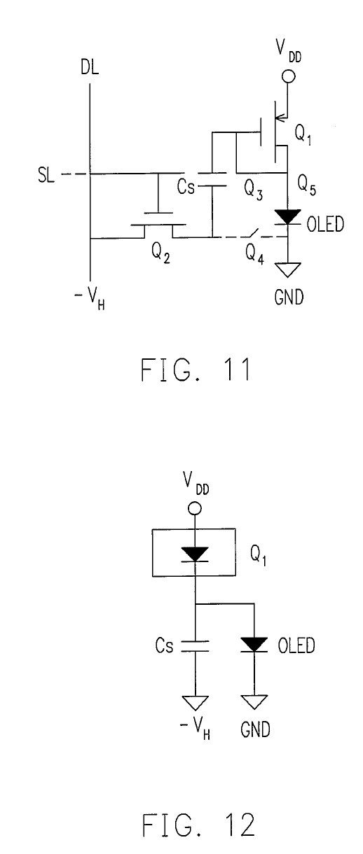

In the reverse phase, the thin-film transistors Q₁, Q₂, Q₃ and Q₅ are turned on, whereas Q₄ is turned off. Therefore, the gate terminal and the drain terminal of the thin-film transistor Q₁ are connected together, the second terminal of the storage capacitor Cs is connected to the data line DL, the anode of the organic light-emitting diode OLED is connected to the drain terminal of the thin-film transistor Q₁. The connection of the above components is shown in solid lines in FIG. 11. Because the TFT Q₃ is turned on, the driving switch Q₁ is equivalent to a diode, and the circuit in this embodiment is equivalent to the circuit depicted in FIG. 12. In the reverse phase, the negative voltage −V_{H} is provided to the data line DL, lowering the gate voltage V_{G} at the gate terminal of Q₁ to V_{DD}−Vₜₕ−V_{H}, as shown in FIG. 7. The negative voltage −V_{H} is negative enough to satisfy the inequality V_{H}>V_{DD}−Vₜₕ. In other words, the gate voltage V_{G} will be lower than 0V and there will be a reverse bias across the organic light-emitting diode OLED to eliminate the polarization phenomenon.

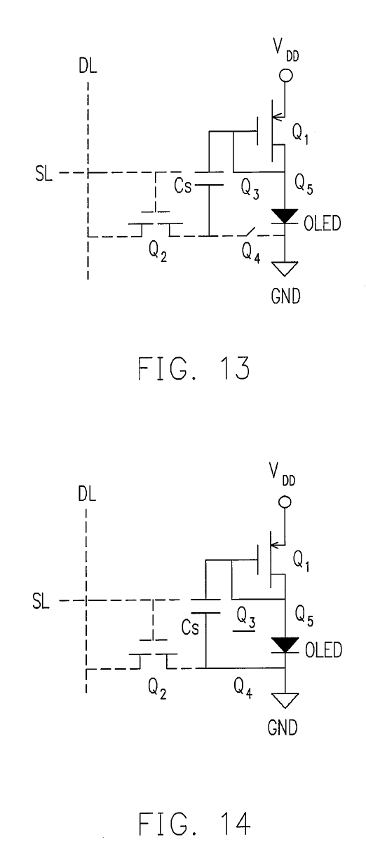

As shown in FIG. 7, the gate voltage V_{G} falls to V_{DD}−Vₜₕ−V_{H} at first, and then the gate voltage V_{G} rises towards 0V due to the charging of the storage capacitor Cs. If the gate voltage V_{G} rises to 0V or gets higher, the organic light-emitting diode OLED will be turned on and start to emit light. To avoid this problem, the driving circuit in this embodiment has to enter the clamping phase again before the gate voltage V_{G} rises to 0V. There are two transient steps before the circuit enters the clamping phase again. The first step is turning off the TFT Q₂ to remove the negative voltage −V_{H}. The connection of the components of the circuit after the first step is shown in solid lines in FIG. 13. The second step is turning on the TFT Q₄. The connection after the second step is shown in solid lines in FIG. 14. At this moment, the gate voltage V_{G} will rises to the point V_{P} in FIG. 7, generating a reverse bias to turn off the driving switch Q₁. At the same time, the organic light-emitting diode OLED provides a path for the storage capacitor Cs to discharge. Although the organic light-emitting diode OLED does emit light in this short moment, the duration is too short to affect its overall brightness. When the voltage across the storage capacitor Cs lowers to V_{DD}−Vₜₕ to turn on the driving switch Q₁, the TFT Q₅ is turned off and the driving circuit in this embodiment is back into the clamping phase.

The present invention also comprehends a method for driving pixels of an organic light-emitting display. The main steps of the method include storing the threshold voltage Vₜₕ of the thin-film transistor Q₁ in the storage capacitor Cs before the TFT Q₂ connected to the scan line SL is turned on, determining the conducting time of the thin-film transistor Q₁ according to the data voltage V_{data} and the reference voltage V_{sweep}, and applying a reverse bias across the organic light-emitting diode OLED during a period without an external electric field of the organic light-emitting diode OLED. The details of the method are not described here because anyone skilled in the related art should be able to implement the method easily after referring to the above embodiments of the present invention.

As can be seen in the above embodiments, the present invention stores the threshold voltage of the driving switch in a storage capacitor such that the threshold voltage will cancel out itself, therefore eliminating the problem of discordant brightness caused by threshold voltage shifts. Besides, the present invention applies reverse bias to eliminate the polarization phenomenon. Consequently the material lifetime of organic light-emitting diodes is prolonged and the movement of electrons and holes inside the diodes is enhanced. Furthermore, the present invention advances the clamping of the threshold voltage of the driving switch. The period with an external electric field of organic light-emitting diodes is not occupied by the clamping. Therefore the timing control of the TFT in the driving circuit can be relaxed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for driving pixels of an organic light-emitting display, characterized by:
storing a threshold voltage factor of a thin-film transistor in a storage capacitor before a switch connected to a scan line is turned on.

2. The method of claim 1, further comprising:
driving an organic light-emitting diode with the thin-film transistor.

3. The method of claim 2, further comprising:
determining a conducting time of the thin-film transistor according to a data voltage and a reference voltage.

4. The method of claim 2, further comprising:
applying a reverse bias across the organic light-emitting diode during a period without an external electric field of the organic light-emitting diode.
